(19) United States
(12) Patent Application Publication
(10) Pub. No.: US 2015/0123152 A1
(43) Pub. Date: May 7, 2015

(54) LIGHT-EMITTING ELEMENT

(71) Applicant: EPISTAR CORPORATION, Hsinchu (TW)

(72) Inventors: CHI-NAN LIN, Hsinchu (TW); CHIEN-FU SHEN, Hsinchu (TW); YU-CHEN YANG, Hsinchu (TW); Ching-Tung Tseng, Hsinchu (TW); Cheng-Hsiang Ho, Hsinchu (TW); Chun-Wei Chang, Hsinchu (TW); Chen Ou, Hsinchu (TW)

(21) Appl. No.: 14/533,549

(22) Filed: Nov. 5, 2014

(30) Foreign Application Priority Data
Nov. 5, 2013 (TW) 102140226
Feb. 12, 2014 (TW) 103104673

(51) Int. Cl. H01L 33/00; H01L 33/44; H01L 33/42; H01L 33/14; H01L 33/22

(52) U.S. Cl. CPC H01L 33/002; H01L 33/145; H01L 33/22; H01L 33/42; H01L 33/44; H01L 2933/0016; H01L 2933/0025
USPC 257/95; 438/22

(57) ABSTRACT

A light-emitting element includes a light-emitting stacked layer including an upper surface, wherein the upper surface includes a first flat region; a protective layer including a current blocking region on the first flat region; and a cap region on the upper surface, wherein the current blocking region is spatially separate from the cap region; and a first electrode covering the current blocking region.

### CROSS-REFERENCE TO RELATED APPLICATIONS

This application claims priority to and the benefit of Taiwan Application Serial Number 102140226 filed on Nov. 5, 2013 and Taiwan Application Serial Number 103104673 filed on Feb. 12, 2014, which are incorporated by reference in its entirety.

### BACKGROUND

1. Technical Field

The present disclosure relates to a light-emitting element, more particularly, to a light-emitting element with high manufacturing yield rate.

2. Description of the Related Art

Optoelectronic devices, such as light emitting diodes (LEDs), have been widely applied to optical displays, traffic signals, data storage devices, communication systems, lighting devices and medical instruments. Besides, LEDs can be connected to and combined with other components to construct a lighting device. FIG. 1 shows a conventional art of a light-emitting device. As shown in FIG. 1, a light-emitting device 1 includes a submount 12 comprising a circuit 14, a solder 16 formed on the submount 12 to fix a LED 11 on the submount 12 and electrically connect the LED 11 and the circuit 14 on the submount 12, and electrical connections 18 to electrically connect electrodes 15 of the LED 11 and the circuit 14 on the submount 12. The submount 12 can be a lead frame or a large mounting substrate.

### SUMMARY OF THE DISCLOSURE

A light-emitting element includes a light-emitting stack including an upper surface, wherein the upper surface includes a first flat region; a protective layer including a current blocking region on the first flat region; and a cap region on the upper surface, wherein the current blocking region and the cap region are separated spatially; and a first electrode covering the current blocking region.

A method for manufacturing a light-emitting element includes providing a light-emitting stack; forming a protective layer on the light-emitting stack; removing a part of the protective layer to form a first opening and a current blocking region in the first opening; and forming a first electrode covering the current blocking region.

A light-emitting element includes a light-emitting stack including an upper surface and a lateral surface, wherein the upper surface includes a first region and a second region, and an area of the second region is smaller than that of the first region; a protective layer, including a cap region formed on the lateral surface and the second region and exposing the first region; and a first electrode formed on the upper surface.

### BRIEF DESCRIPTION OF THE DRAWINGS

FIG. 1 shows a conventional light-emitting element.

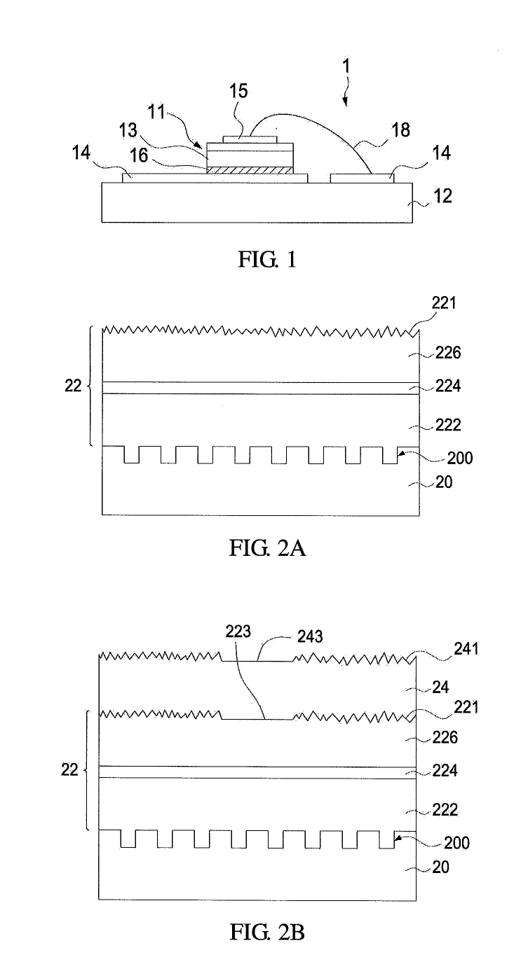

FIGS. 2A˜2D show a process of manufacturing the light-emitting element in accordance with one embodiment of present disclosure.

FIG. 2E shows a top view of the light-emitting element in FIG. 2D of present disclosure.

FIG. 3 shows a cross-sectional view of the light-emitting element in accordance with another embodiment of present disclosure.

FIG. 4 shows a cross-sectional view of the light-emitting element in accordance with another embodiment of present disclosure.

FIG. 5 shows an exploded view of a bulb in accordance with another embodiment of present disclosure.

### DETAILED DESCRIPTION OF THE EMBODIMENTS

To better and concisely explain the disclosure, the same name or the same reference number given or appeared in different paragraphs or figures along the specification should has the same or equivalent meanings while it is once defined anywhere of the disclosure.

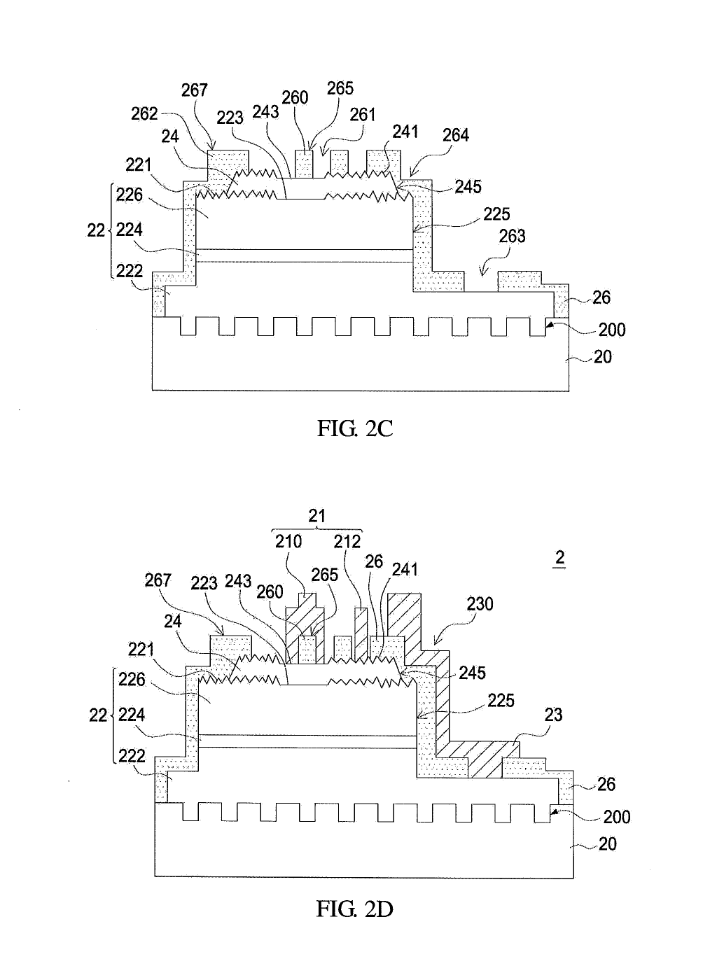

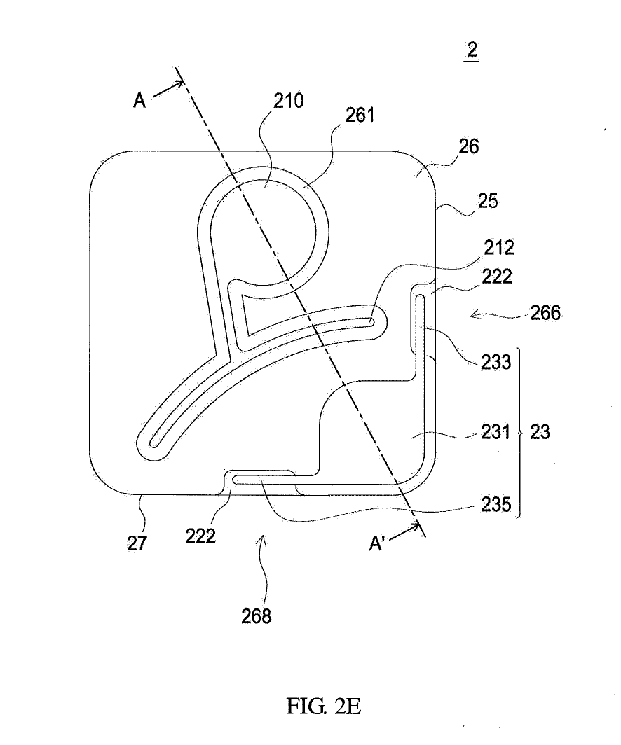

FIGS. 2A˜2D show a manufacturing process of a light-emitting element in accordance with the first embodiment. As shown in FIG. 2A, a light-emitting stack 22 is formed on a substrate 20. The light-emitting stack 22 includes a first semiconductor layer 222, an active layer 224 and a second semiconductor layer 226 formed on the substrate 20 sequentially. The second semiconductor layer 226 has a first rough surface 221. As shown in FIG. 2B, a first flat region 223 is formed on the first rough surface 221; a transparent conductive oxide layer 24 is formed the second semiconductor layer 226, wherein the transparent conductive oxide layer 24 has a second rough surface 241 and a second flat region 243 formed on the second rough surface 241. The roughness of the second flat region 243 is substantially same as that of the first flat region 223. As shown in FIG. 2C, a part of the transparent conductive oxide layer 24 and a part of the light-emitting stack 22 are removed to expose a portion of the first semiconductor layer 222 and the first rough surface 221. A protective layer 26 is formed on the light-emitting stack 22 and the transparent conductive oxide layer 24 and thereby to cover a lateral side 225 of the light-emitting stack 22 and a second lateral side of the transparent conductive oxide layer 245. Since the levels of the first rough surface 221 and the second rough surface 241 are different, a first step region 264 is formed on the first rough surface 221 when the protective layer 26 is formed on the second lateral side 245. A part of the protective layer 26 is removed to form a first opening 261 so as to expose the second rough surface 241 and the second flat region 243, a second opening 263 exposes the first semiconductor layer 222, a current blocking region 260 is formed on the second flat region 243, and a cap region 262 is formed on the second rough surface 241, wherein the distance between an upper surface 265 of the current blocking region 260 and the active layer 224 is substantially same as the distance between an upper surface 267 of the cap region 262 and the active layer 224. Then, as shown in FIG. 2D, forming a first electrode 21 on the first opening 261 and the protective layer 26 to cover the current blocking region 260; and forming a second electrode 23 on the second opening 263 and the protective layer 26, wherein a part of the second electrode 23 is formed on the second semiconductor layer 226 and the transparent conductive oxide layer 24 so as to cover the first step region 264 and form a second step region 230. FIG. 2E shows a top view of the light-emitting element 2. FIG. 2D is a cross-sectional view along line AA′ in FIG. 2E. As shown in FIG. 2E, the first electrode 21 comprises a first pad 210 and a first extending part 212 which extends from the first pad 210. The second electrode 23 comprises a second pad 231 and a second extending part 233 and a third extending part 235 which extend from the second pad 231. The light-emitting element 2 comprises a first side 25 and a second side 27 adjacent to the first side 25. A part of the protective layer 26 and a part of the light-emitting stack 22 are removed to from a third opening 266 and a fourth opening 268 exposing the first semiconductor layer 222. The third opening 266 locates at the first side 25, and the fourth opening 268 locates at the second side 27. The second extending part 233 extends to the third opening 266 and contacts with the exposed first semiconductor layer 222. The third extending part 235 extends to the fourth opening 268 and contacts with the exposed first semiconductor layer 222 to improve current spreading and luminous efficiency. The protective layer 26 and the light-emitting stack 22 under the second extending part 233 and the third extending part 235 are not entirely removed, thereby to avoid decreasing the light-emitting area and decreasing luminous efficiency of the light-emitting element 2.

The first electrode 21 and/or the second electrode 23 are used to connect to an external voltage. The material of the first electrode 21 and the second electrode 23 can be transparent conductive material or metal material. The transparent conductive material includes but is not limited to ITO, InO, SnO, CTO, ATO, AZO, ZTO, GZO, IWO, ZnO, AlGaAs, GaN, GaP, GaAs, GaAsP, IZO, or diamond-like Carbon (DLC). The metal material includes but is not limited to Al, Cr, Cu, Sn, Au, Ni, Ti, Pt, Pb, Zn, Cd, Sb, Rh, Ag, Mg or alloy of the materials described above. A part of the second electrode 23 is formed on the transparent conductive oxide layer 24 to increase the area of the second electrode 23. Such configuration benefits later manufacturing process such as wire bonding. The first electrode 21 covers at least a lateral surface of the current blocking region 260 to increase a contact area with the current blocking region 260. The adhesion between the first electrode 21 and the current blocking region 260 is improved so as to prevent the first electrode 21 from peeling off the current blocking region 260 during later processes (ex. wire bonding) and to avoid decreasing the manufacturing yield rate of the light-emitting element 2.

The protective layer 26 is used to protect the light-emitting stack 22 and improve robustness of the structure. Besides, the protective layer 26 is also used to electrically isolate parts of the second electrode 23 and the light-emitting stack 22, and prevent them from short. The thickness of the protective layer 26 is about 1 μm to 3 μm. If the thickness is smaller than 1 μm, leakage current occurs; if the thickness is larger than 3 μm, the first electrode 21 is not able to cover the current blocking region 260 so that the chance of peeling is increased. The current blocking region 260 is formed by removing a part of the protective layer 26. The current blocking region 260 and the cap region 262 are separated spatially and are not contact directly. In another embodiment, the current blocking region 260 is connected to the cap region 262. The current blocking region is used to restrain currents flow through the light-emitting stack 22 under the first electrode 21 and reduce the chance that light emits from the light-emitting stack 22 is absorbed by the first electrode 21, so that reduction in luminous efficiency of the light-emitting element 2 is prohibited. Furthermore, the current blocking region 260 is also used to connect the first electrode 21 and the transparent conductive oxide layer 24 so as to reduce the possibility of peeling of the first electrode 21 and improve the yield rate. The protective layer 26 can be made of electrically insulative material such as polyimide (PI), Benzocyclobutene (BCB), Perfluorocyclobutane (PFCB), MgO, Sub, Epoxy, Acrylic resin, Cycle Olefin copolymer (COC), Polymethylmethacrylate (PMMA), Polyethylene terephthalate (PET), Polycarbonate (PC), Polyetherimide, Fluorocarbon Polymer, Glass, Al₂O₃, SiOₓ, TiO₂, Ta₂O₅, SiNₓ. MgF₂, Spin-on glass (SOG), diamond, Tetraethyl orthosilicate (TEOS) or combination of the materials described above.

The material of the light-emitting stack 22 can be conductive material which includes one or more than one element selected form Ga, Al, In, P, N, Zn, Cd or Se. The polarities of the first semiconductor layer 220 and the second semiconductor layer 224 are different to generate electrons and electron holes. The second semiconductor layer 224 has a rough upper surface in order to suppress total reflection so as to improve luminous efficiency of the light-emitting device 2. Moreover, the active layer 222 emits one or more than one color light. The light can be visible or invisible. The structure of the active layer 224 can be single heterostructure (SH), double heterostructure (DH), double-side double heterostructure (DDH), multi-quantum well (MQW) structure or quantum dot. As shown in FIG. 2D, the first flat region is substantially formed under the first electrode 21. The width W1 of the first flat region 223 and/or the width W2 of the second flat region 243 is larger than the width W3 of the first pad 210. In this manner, the condition that the light generated by the active layer 224 shoots to the pad 210 and is absorbed can be avoided and total reflection is increased to improve light extraction of the light-emitting element 2. In another embodiment, the first pad 210 covers a part of the second rough surface 241 to increase the contact area between the first pad 210 and the transparent conductive oxide layer 24, and reduce the chance of peeling of the first pad 21 so as to improve yield rate. The transparent conductive layer 24 is transparent to light emitted from the active layer 224. The transparent conductive layer 24 improves ohmic contact between the light-emitting stack 22 and the first electrode 21 as well as current spreading. The material of the transparent conductive layer 24 can be conductive material which includes but is not limited to ITO, InO, SnO, CTO, ATO, AZO, ZTO, GZO, ZnO, MgO, AlGaAs, GaN, GaP, Graphene or IZO.

The substrate 20 supports the light-emitting stack 22 and other layers or other structures which are disposed thereon. The material of the substrate 22 includes a transparent material or an electrically conductive material. The transparent material includes but is not limited to sapphire, diamond, glass, epoxy, quartz, acryl, Al₂O₃, ZnO or AlN, etc. The electrically conductive material can be Cu, Al, Mo, Sn, Zn, Cd, Ni, Co, diamond like Carbon (DLC), Graphite, Carbon fiber, metal matrix composite (MMC), ceramic matrix composite (CMC), Si, IP, ZnSe, GaAs, SiC, GaP, GaAsP, InP, LiGaO₂ or LiAlO₂. Among these materials, sapphire, GaAs, SiC and Si can be used as a growth substrate. The substrate 20 has a patterned upper surface 200 which can improve epitaxy quality and scatter the light emitted from the light-emitting stack 22 so as to improve luminous efficiency of the light-emitting element 2.

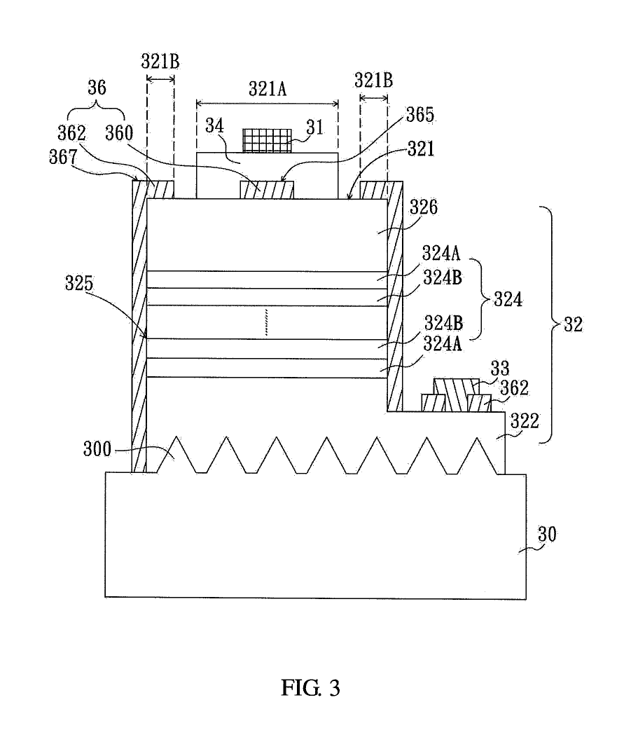

The light-emitting element in accordance with the second embodiment of this application is shown in FIG. 3. The embodiment is a modification of the first embodiment. In this embodiment, the light-emitting element 3 comprises a light-emitting stack 32 formed on a substrate 30. The light-emitting stack 32 comprises an upper surface 321 and lateral surfaces 325. The light-emitting stack 32 comprises a first semiconductor layer 322, an active layer 324 and a second semiconductor layer 326 formed on the substrate 30 sequentially, wherein the second semiconductor layer 326 comprises the upper surface 321. A protective layer 36 is formed on the light-emitting stack 32 and comprises a current blocking region 360 formed on a first region 321A of the upper surface 321. And a cap region 362 covers the lateral surface 325 of the light-emitting stack 32 and a second region 321B of the upper surface 321. The distance between the upper surface 365 of the current blocking region 360 and the active layer 324 is substantially same as the distance between the upper surface 367 of the cap region 362 and the active layer 324. The active layer 324 generates light when external current flows into it. The structure of the active layer 324 forms a heterostructure or a double heterostructure with the first semiconductor layer 322 and the second semiconductor layer 326. The active layer 324 also can be a quantum well structure formed by barrier layers and well layers, comprising single quantum well structure or multi-quantum well structure. In this embodiment, the active layer 324 is a multi-quantum structure which comprises barrier layers 324A and well layers 324B.

A transparent conductive oxide layer 34 is formed on the second semiconductor layer 326. The location of the transparent layer 34 is in the first region 321A and the transparent layer 34 covers the current blocking region 360. The cap region 362 covers the second region 321B and directly contacts the second semiconductor layer 326. The area of the upper surface 321 which is not covered by the transparent layer 34 is equal to or larger than the area of the second region 321B. The area of the second region 321B is smaller than that of the first region 321A. The area of the second region 321B can be smaller than 15% of the area of the first region 321A; the area of the second region 321B can be 2-15% of the area of the first region 321A. In this embodiment, the area of the second region 321B is 3-10% of the area of the first region 321A. While external current flows into the light-emitting element, the current can be spread by the transparent conductive oxide layer 34 at first and then inject into the active layer 324. The active layer 324 under the transparent conductive oxide layer 34 serves to emit light, and the light can be extracted by the transparent conductive oxide layer 34. However, the difference in refractive index between the protective layer 36 and the transparent conductive oxide layer 34 causes internal total reflection. The internal total reflection causes the light extraction efficiency reduction. Thus, people who skills in the art have to make efforts on choosing a suitable material of the protective layer 36 and designing an appropriate thickness to reduce internal total reflection. Therefore, the protective layer does not cover the transparent conductive oxide layer preferably to avoid the internal total reflection between the transparent conductive oxide layer and the protective layer.

Without influence on brightness, the cap region 362 of the protective layer 36 is able to partially cover the upper surface 321, such as the second region 321B. One purpose is the cap region 362 can be assured to entirely cover the lateral surfaces during the process of forming an opening to separate the cap region 362 and the current blocking region 360; another purpose is adhesion between the light-emitting stack 32 and the cap region 362 is improved by forming the cap region 362 on the second region 321B.

A first electrode 31 is formed on the transparent conductive oxide layer 34 and is located at a place corresponding to the current blocking layer 360. A second electrode 33 is formed on the first semiconductor layer 322. The cap region 362 can be formed between the second electrode 33 and the first semiconductor layer 322. The cap region comprises an opening exposing the first semiconductor layer 322. One portion of the second electrode 33 is formed on the cap region 362 and another portion of the second electrode 33 contacts the exposed first semiconductor layer 322.

Since the second embodiment is a modification of the first embodiment, the condition listed in the first embodiment can also be applied in the second embodiment. Besides, the substrate 30 comprises a patterned upper surface 300, which serves to improve epitaxy quality of the light-emitting stack 32 on the substrate 30 and to scatter light emitted from the light-emitting stack 32 thereby to improve luminous efficiency of the light-emitting element 3. The pattern of the upper surface 300 includes cones with a circular bottom and a tip. The cross-section of the cone is a triangle. The pattern of the upper surface 300 can also be selected from polygonal pyramids. The pattern of the substrate 30 can be formed by photolithographic process. The upper surface of the substrate 30 can be etched by dry-etching or wet-etching process. In this embodiment, dry-etching process is applied to form the pattern.

In another embodiment, on the current blocking region 360, openings are partially formed in the transparent conductive oxide layer 34 under the first electrode 31 to expose a part of the current blocking region 360 and to make the first electrode 31 contact with the current blocking region 360. Openings can also be partially formed in the current blocking layer 360 described above to expose the second semiconductor layer 326 so that the first electrode extends downward to contact with the second semiconductor layer 326 via the opening of the transparent conductive oxide layer 34 and the opening of the current blocking region 360.

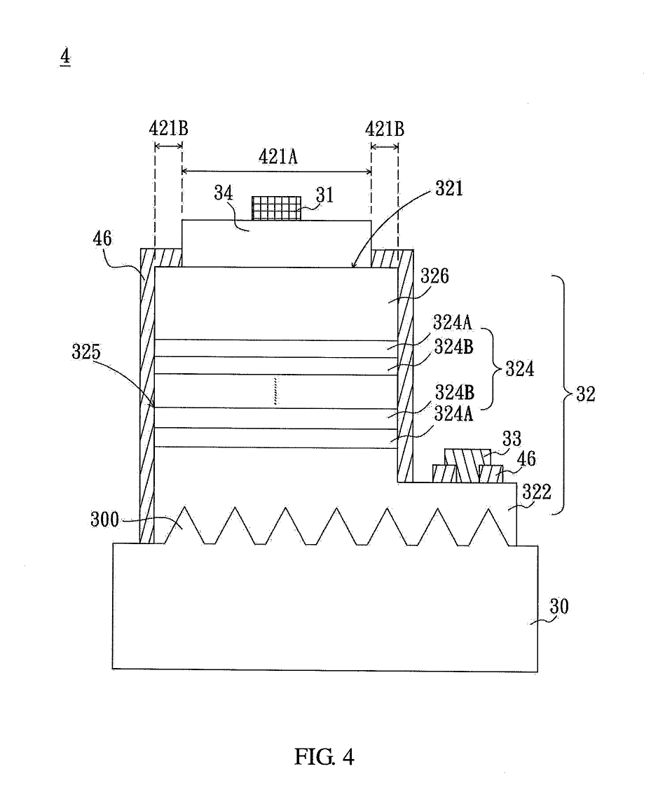

FIG. 4 shows the third embodiment of the application. The transparent conductive oxide layer 34 of the light-emitting element 4 partially or entirely covers the upper surface 321. While the transparent conductive oxide layer 34 partially covers the upper surface 321, the protective layer 46 of the light-emitting element 4 covers the lateral surface 325 and the upper surface 321 of the light-emitting stack 32. In another embodiment, the protective layer 46 also partially covers the transparent conductive oxide layer 34 while the transparent conductive oxide layer 34 entirely covers the upper surface 321. The protective layer 46 of the light-emitting element 4 covers the lateral surface 325 and a part of the transparent conductive oxide layer 34.

The area of the upper surface 321 covered by the protective layer 46 is a second region 421B of the upper surface 321; the area not covered by the protective layer 46 is a first region 421A of the upper surface 321. The area of the second region 421B is smaller than that of the first region 421A. The area of the second region 421B is below 15% of the area of the first region 421A. In this embodiment, the area of the second region 421B is 3%-10% of the area of the first region 421A.

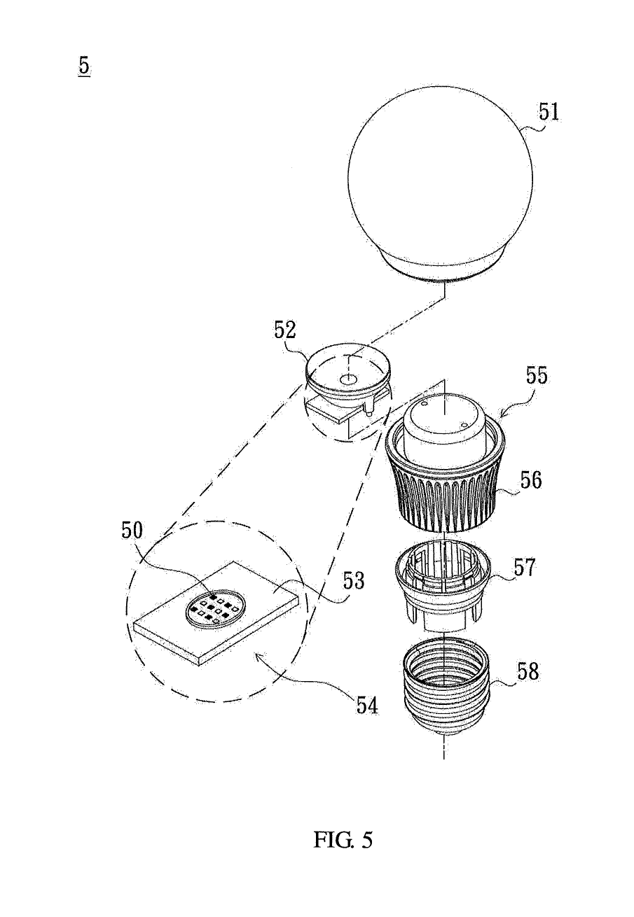

FIG. 5 shows an exposed view of a light bulb. The light bulb 5 includes a cover 51, a lens 52 set in the cover 51, a lighting module 54 formed under the lens 52, a lamp holder 55 which supports the lighting module 54 including a heat sink 56, a connecting part 57, and an electrical connector 58. The connecting part 57 connects the lamp holder 55 and the electrical connector 58. The lighting module 54 includes a carrier 53 and a plurality of light-emitting elements according to any of the embodiments described above formed on the carrier 53.

It will be apparent to those having ordinary skill in the art that various modifications and variations can be made to the devices in accordance with the present disclosure without departing from the scope or spirit of the disclosure. In view of the foregoing, it is intended that the present disclosure covers modifications and variations of this disclosure provided they fall within the scope of the following claims and their equivalents.

What is claimed is:

1. A light-emitting element, comprising:
a light-emitting stack, comprising an upper surface, wherein the upper surface comprises a first flat region;
a protective layer, comprising
a current blocking region on the first flat region; and
a cap region on the upper surface, wherein the current blocking region and the cap region are separated spatially; and
a first electrode covering the current blocking region.

2. The light-emitting element of claim 1, wherein the light-emitting stack comprises:
a first semiconductor layer;
a second semiconductor layer formed between the first semiconductor layer and the current blocking region;
an active layer formed between the first semiconductor layer and the second semiconductor layer; and
a second electrode formed on the first semiconductor layer and on a lateral side of the second semiconductor layer, and separated from the first electrode.

3. The light-emitting element of claim 1, wherein the cap region and the current blocking region comprise substantially the same thickness and the same material.

4. The light-emitting element of claim 1, wherein the protective layer further comprises an opening between the cap region and the current blocking region, wherein the first electrode fills in the opening.

5. The light-emitting element of claim 1, wherein the upper surface comprises a rough surface.

6. The light-emitting element of claim 1, further comprising a second electrode, wherein the protective layer comprises an opening and the second electrode fills in the opening.

7. The light-emitting element of claim 1, further comprising a transparent conductive oxide layer formed between the protective layer and the light-emitting stack, comprising a second flat region formed between the first flat region and the current blocking region, wherein a roughness of the first flat region is substantially same as a roughness of the second flat region.

8. The light-emitting element of claim 1, further comprising a second electrode, wherein the first electrode comprises a pad and an extending part, wherein the extending part locates between the pad and the second electrode.

9. The light-emitting element of claim 1, wherein a thickness of the protective layer ranges 1 μm to 3 μm.

10. The light-emitting element of claim 1, further comprising a substrate under the light-emitting stack, wherein the substrate comprises a patterned surface.

11. The light-emitting element of claim 1, further comprising:
a first side, wherein the protective layer comprises a first opening passing through a part of the light-emitting stack and formed on the first side;
a second side adjacent to the first side, wherein the protective layer comprises a second opening passing through a part of the light-emitting stack and formed on the second side; and
a second electrode, comprising a first extending part formed in the first opening and a second extending part formed in the second opening.

12. The light-emitting element of claim 1, further comprising a second electrode, wherein the protective layer comprises a first step region on the light-emitting stack, and the second electrode comprises a second step region on the first step region.

13. A method for manufacturing a light-emitting element, comprising:
providing a light-emitting stack;
forming a protective layer on the light-emitting stack;
removing a part of the protective layer to form a first opening and a current blocking region in the first opening; and
forming a first electrode covering the current blocking region.

14. The method of claim 13, before forming the protective layer, further comprising:
roughening the light-emitting stack to form a rough upper surface; and
forming a flat region on the rough upper surface.

15. The method of claim 14, further comprising forming a second electrode on the rough upper surface and on a lateral side of the light-emitting stack after removing a part of the protective layer.

16. The method of claim 13, before forming the protective layer, further comprising:
forming a transparent conductive oxide layer on the light-emitting stack; and
forming a second electrode on the light-emitting stack and on a lateral side of the transparent conductive oxide layer.

17. The method of claim 13, after forming the protective layer, further comprising:
forming a second opening in the protective layer; and
forming a second electrode in the second opening.

18. The method of claim 13, after removing a part of the protective layer, further comprising forming a second electrode on the light-emitting stack separated from the first electrode.

19. The method of claim 13, wherein forming the protective layer comprising forming a first step region on the light-emitting stack.

20. The method of claim 19, further comprising forming a second electrode on the protective layer, wherein the second electrode further comprises a second step region on the first step region.
